(19) United States
(12) Patent Application Publication
(10) Pub. No.: US 2008/0174923 A1
(43) Pub. Date: Jul. 24, 2008

(54) ESD protection scheme for semiconductor devices having dummy pads

(75) Inventors: Yi-Hsun Wu, Hsinchu (TW); Yan-Chih Jiang, Hsinchu (TW); Yu-Chang Lin, Hsinchu (TW); Jian-Hsing Lee, Hsinchu (TW)

Correspondence Address: BIRCH, STEWART, KOLASCH & BIRCH, LLP, P.O. BOX 747, FALLS CHURCH, VA, 22040-0747, US

(73) Assignee: TAIWAN SEMICONDUCTOR MANUFACTURING CO., LTD.

(21) Appl. No.: 11/812,221

(22) Filed: Jun. 15, 2007

Related U.S. Application Data
(63) Continuation-in-part of application No. 11/655,896, filed on Jan. 22, 2007.

(51) Int. Cl. H02H 9/00; H01L 21/336

(52) U.S. Cl. 361/56; 438/237; 257/E21.409

(57) ABSTRACT

A semiconductor device formed in a semiconductor substrate for dissipating electrostatic discharge and/or accumulated charge in an integrated circuit is provided. In one embodiment, the device comprises a semiconductor substrate; a plurality of layers of metal lines formed overlying the substrate; a plurality of via plugs through intermetal dielectric layers between the layers of metal lines and wherein the via plugs interconnect the metal lines; and a dummy pad formed over the plurality of layers of metal lines, the dummy pad having a diode connected thereto and to ground for providing a discharge path for the electrostatic discharge and/or accumulated charge.

### CROSS REFERENCE TO RELATED APPLICATION

This application is a Continuation-In-Part of pending U.S. patent application Ser. No. 11/655,896, filed Jan. 22, 2007, which is incorporated herein for reference.

### BACKGROUND

The present invention relates generally to protection schemes for semiconductor devices from ESD (electrostatic discharge) and/or accumulated charges, and more particularly, to protection schemes for semiconductor devices having dummy pads from ESD and/or accumulated charges.

Isolated or dummy bond pads having solder balls formed thereon are often employed in the fabrication of semiconductor devices for improving the mechanical robustness of these devices. These dummy pads are isolated and are often not electrically connected to any circuit. However, accumulated charges or ESD often accumulate on these dummy pads and as a result discharge to neighboring devices, thereby damaging these devices or the top metal lines in the devices.

This problem is illustrated in FIG. 1. FIG. 1 shows a cross-sectional view of a semiconductor device 10 having a plurality of metal lines M1, M2, M3 formed overlying a substrate and a plurality of via plugs 40 through intermetal dielectric layers (not shown) formed between the layers of metal lines. A dummy pad 20 having a solder ball 30 formed thereon is positioned above a top most metal line M3. When accumulated charges or ESD 70 build up on dummy pad 20, they discharge to ground thereby damaging an internal circuit 60 in an active area 50 of the semiconductor device 10.

For these reasons and other reasons that will become apparent upon reading the following detailed description, there is a need for a protection scheme for semiconductor devices having dummy pads from ESD and/or accumulated charges.

### SUMMARY

The present invention is directed to a semiconductor device formed in a semiconductor substrate for dissipating electrostatic discharge and/or accumulated charge in an integrated circuit. In one embodiment, the device comprises a semiconductor substrate; a plurality of layers of metal lines formed overlying the substrate; a plurality of via plugs through intermetal dielectric layers between the layers of metal lines and wherein the via plugs interconnect the metal lines; and a dummy pad formed over the plurality of layers of metal lines, the dummy pad having a diode connected thereto and to ground for providing a discharge path for the electrostatic discharge and/or accumulated charge.

In another embodiment, the device comprises a semiconductor substrate; a plurality of layers of metal lines formed overlying the substrate; a plurality of via plugs through intermetal dielectric layers between the layers of metal lines and wherein the via plugs interconnect the metal lines; and a dummy pad formed over the plurality of layers of metal lines, the dummy pad having a gate-grounded NMOS (ggNMOS) connected thereto, the drain being connected to the dummy pad and the gate and source being connected to ground for providing a discharge path for the electrostatic discharge and/or accumulated charge.

In yet another embodiment, the device comprises a semiconductor substrate; a plurality of layers of metal lines formed overlying the substrate; a plurality of via plugs through intermetal dielectric layers between the layers of metal lines and wherein the via plugs interconnect the metal lines; and a dummy pad formed over the plurality of layers of metal lines, the dummy pad comprising: a gate-grounded NMOS (ggNMOS), the drain being connected to the dummy pad and the gate and source being connected to ground; and a diode connected to the dummy pad and to ground for providing a discharge path for the electrostatic discharge and/or accumulated charge.

### BRIEF DESCRIPTION OF THE DRAWINGS

The features, aspects, and advantages of the present invention will become more fully apparent from the following detailed description, appended claims, and accompanying drawings in which:

FIG. 1 is a cross-sectional view of a semiconductor device with dummy pads showing a discharge path of accumulated charge or electrostatic discharge from the dummy pad to an integrated circuit.

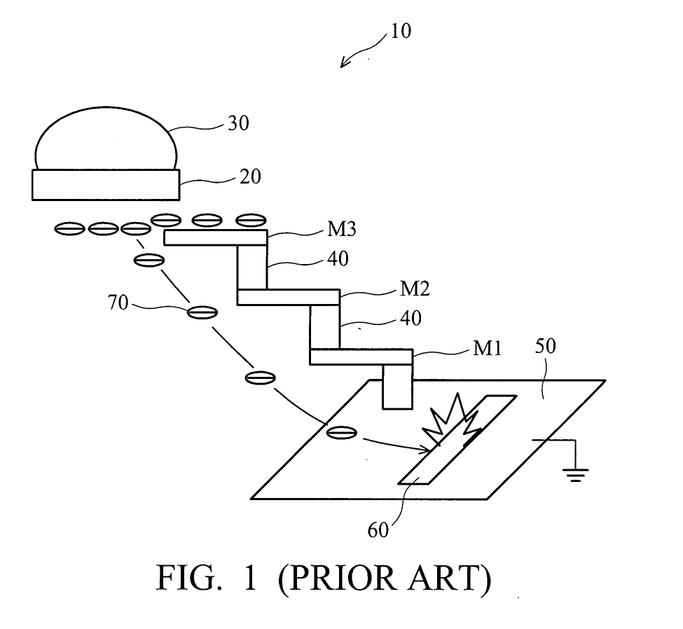

FIG. 2A is a cross-sectional view of a semiconductor device with dummy pads having an ESD protection scheme showing a discharge path of accumulated charge or electrostatic discharge from the dummy pad to ground, according to one embodiment of the present invention.

FIG. 2B is a cross-sectional view of a semiconductor device with dummy pads having an ESD protection scheme showing a discharge path of accumulated charge or electrostatic discharge from the dummy pad to ground, according to another embodiment of the present invention.

### DETAILED DESCRIPTION

In the following description, numerous specific details are set forth to provide a thorough understanding of the present invention. However, one having an ordinary skill in the art will recognize that the invention can be practiced without these specific details. In some instances, well-known structures and processes have not been described in detail to avoid unnecessarily obscuring the present invention.

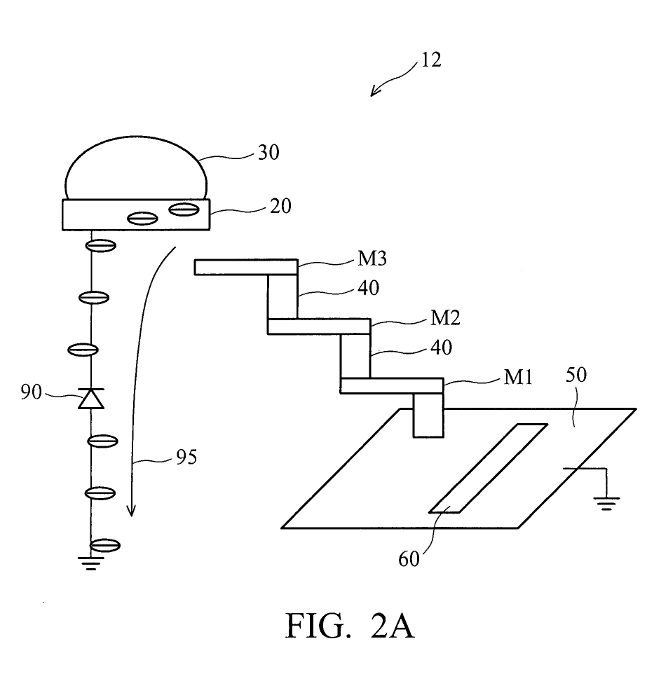

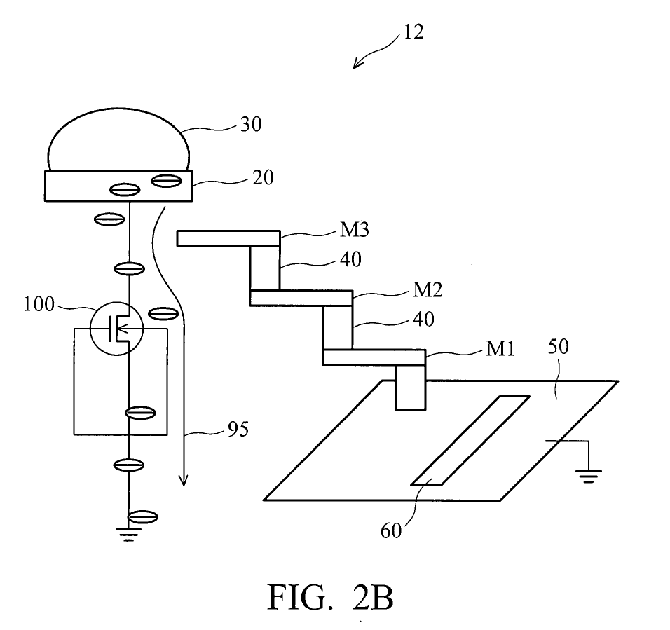

A first embodiment of the present invention will now be described with reference to FIG. 2A.

FIG. 2A is a cross-sectional view of a semiconductor device with dummy pads having an ESD protection scheme showing a discharge path of accumulated charge or electrostatic discharge from the dummy pad to ground, according to one embodiment of the present invention. The semiconductor device 12 has a plurality of metal lines M1, M2, M3 formed overlying a substrate and a plurality of via plugs 40 through intermetal dielectric layers (not shown) formed between the layers of metal lines, the via plugs 40 interconnecting the metal lines. A dummy pad 20 having a solder ball 30 formed thereon is positioned above the top most metal line M3. The protection scheme according to this embodiment comprises a diode 90 connected between the dummy pad 20 and ground. The cathode of the diode 90 is connected to the dummy pad 20 and the anode of the diode 90 is connected to ground. In one embodiment, the diode is a reverse diode. The purpose of the diode 90 is to gradually discharge the charges accumulated on dummy pad 20 and to avoid damage to an internal circuit 60. Instead of accumulated charges or ESD 95 built up on dummy pad 20 discharging to ground by way of the plurality of metal lines and vias damaging circuit 60 in an active area 50, the protection scheme of the present invention provides a low resistance discharge path for these harmful charges.

A second embodiment of the present invention will now be described with reference to FIG. 2B.

FIG. 2B is a cross-sectional view of a semiconductor device with dummy pads having an ESD protection scheme showing a discharge path of accumulated charge or electrostatic discharge from the dummy pad to ground, according to another embodiment of the present invention. The protection scheme according to this embodiment comprises a gate-grounded NMOS (ggNMOS) transistor 100 connected between the dummy pad 20 and ground. The ggNMOS 100 has a drain connected to the dummy pad 20 and a gate and a source both connected to ground. When an accumulated charge or ESD 95 accumulates on dummy pad 20, the charge is released through the ggNMOS. Therefore, the ESD charge is not applied to the circuit 60, and the circuit is protected.

In another embodiment, the protection scheme can comprise of both a diode and a ggNMOS transistor connected between the dummy pad and ground to provide a discharge path to ground away from the circuit to be protected.

In the preceding detailed description, the present invention is described with reference to specifically exemplary embodiments thereof. It will, however, be evident that various modifications, structures, and changes may be made thereto without departing from the broader spirit and scope of the present invention, as set forth in the claims. The specification and drawings are, accordingly, to be regarded as illustrative and not restrictive. It is understood that the present invention is capable of using various other combinations and environments and is capable of changes or modifications within the scope of the inventive concept as expressed herein.

What is claimed is:

1. A semiconductor device formed in a semiconductor substrate for protecting an integrated circuit from electrostatic discharge and/or accumulated charge, the device comprising:
a semiconductor substrate;
a plurality of layers of metal lines formed overlying the substrate;
a plurality of via plugs through intermetal dielectric layers between the layers of metal lines and wherein the via plugs interconnect the metal lines; and
an isolated pad formed over the plurality of layers of metal lines, the isolated pad having a diode connected thereto and to ground for providing a discharge path for the electrostatic discharge and/or accumulated charge.

2. The semiconductor device of claim 1, wherein the isolated pad is a dummy pad.

3. The semiconductor device of claim 1, wherein the dummy pad is connected to a dummy circuit.

4. The semiconductor device of claim 1, wherein the dummy pad is connected to a dummy active region (OD).

5. The semiconductor device of claim 1, wherein the cathode of the diode is connected to the dummy pad and the anode of the diode is connected to ground.

6. The semiconductor device of claim 1, wherein the diode is a reverse diode.

7. A semiconductor device formed in a semiconductor substrate for protecting an integrated circuit from electrostatic discharge and/or accumulated charge, the device comprising:
a semiconductor substrate;
a plurality of layers of metal lines formed overlying the substrate;
a plurality of via plugs through intermetal dielectric layers between the layers of metal lines and wherein the via plugs interconnect the metal lines; and
a dummy pad formed over the plurality of layers of metal lines, the dummy pad having a gate-grounded NMOS (ggNMOS) connected thereto, the drain being connected to the dummy pad and the gate and source being connected to ground for providing a discharge path for the electrostatic discharge and/or accumulated charge.

8. A semiconductor device formed in a semiconductor substrate for protecting an integrated circuit from electrostatic discharge and/or accumulated charge, the device comprising:
a semiconductor substrate;
a plurality of layers of metal lines formed overlying the substrate;
a plurality of via plugs through intermetal dielectric layers between the layers of metal lines and wherein the via plugs interconnect the metal lines; and
a dummy pad formed over the plurality of layers of metal lines, the dummy pad comprising:
a gate-grounded NMOS (ggNMOS), the drain being connected to the dummy pad and the gate and source being connected to ground; and
a diode connected to the dummy pad and to ground for providing a discharge path for the electrostatic discharge and/or accumulated charge.

9. The semiconductor device of claim 8, wherein the cathode of the diode is connected to the dummy pad and the anode of the diode is connected to ground.

10. The semiconductor device of claim 8, wherein diode is a reverse diode.

11. A method for forming a semiconductor device in a semiconductor substrate for protecting an integrated circuit from electrostatic discharge and/or accumulated charge, the method comprising:
providing a semiconductor substrate;
forming a plurality of layers of metal lines overlying the substrate;
forming a plurality of via plugs through intermetal dielectric layers between the layers of metal lines and wherein the via plugs interconnect the metal lines; and
providing a dummy pad over the plurality of layers of metal lines, the dummy pad having a diode connected thereto and to ground for providing a discharge path for the electrostatic discharge and/or accumulated charge.

12. The method of claim 11, wherein the cathode of the diode is connected to the dummy pad and the anode of the diode is connected to ground.

13. The method of claim 11, wherein the diode is a reverse diode.

14. A method for forming a semiconductor device in a semiconductor substrate,for protecting an integrated circuit from electrostatic discharge and/or accumulated charge, the method comprising:
providing a semiconductor substrate;
forming a plurality of layers of metal lines overlying the substrate;
forming a plurality of via plugs through intermetal dielectric layers between the layers of metal lines and wherein the via plugs interconnect the metal lines; and
providing a dummy pad over the plurality of layers of metal lines, the dummy pad having a gate-grounded NMOS (ggNMOS) connected thereto, the drain being connected to the dummy pad and the gate and source being connected to ground for providing a discharge path for the electrostatic discharge and/or accumulated charge.

15. A method for forming a semiconductor device in a semiconductor substrate for protecting an integrated circuit from electrostatic discharge and/or accumulated charge, the method comprising:
providing a semiconductor substrate;
forming a plurality of layers of metal lines overlying the substrate;
forming a plurality of via plugs through intermetal dielectric layers between the layers of metal lines and wherein the via plugs interconnect the metal lines; and
providing a dummy pad over the plurality of layers of metal lines, the dummy pad comprising:
a gate-grounded NMOS (ggNMOS), the drain being connected to the dummy pad and the gate and source being connected to ground; and
a diode connected to the dummy pad and to ground for providing a discharge path for the electrostatic discharge and/or accumulated charge.

16. The method of claim 15, wherein the cathode of the diode is connected to the dummy pad and the anode of the diode is connected to ground.

17. The method of claim 15, wherein the diode is a reverse diode.
